(19) United States
(12) Patent Application Publication
(10) Pub. No.: US 2014/0183669 A1
(43) Pub. Date: Jul. 3, 2014

(54) RESONANT SENSOR WITH ASYMMETRIC GAPPED CANTILEVERS

(71) Applicants: Yong Xu, Troy, MI (US); Qinglong Zeng, Detroit, MI (US); Yating Hu, Detroit, MI (US); Yefa Li, Detroit, MI (US); Hongen Tu, Detroit, MI (US)

(72) Inventors: Yong Xu, Troy, MI (US); Qinglong Zeng, Detroit, MI (US); Yating Hu, Detroit, MI (US); Yefa Li, Detroit, MI (US); Hongen Tu, Detroit, MI (US)

(73) Assignee: Wayne State University, Detroit, MI (US)

(21) Appl. No.: 13/637,325

(22) PCT Filed: Mar. 25, 2011
(86) PCT No.: PCT/US11/29950

§ 371 Date: Apr. 5, 2013

Related U.S. Application Data
(60) Provisional application No. 61/317,729, filed on Mar. 26, 2010.

(51) Int. Cl. B81B 3/00; B81C 1/00

(52) U.S. Cl. CPC B81B 3/0021; B81C 1/0015
USPC 257/415; 438/52

(57) ABSTRACT

A resonant sensor is provided. The resonant sensor may have a structure including a base portion, a mass portion, and a mechanical beam connecting the base portion to the mass portion. In addition, the structure may include a first sensing beam formed from a sensing material responsive to mechanical strain where a gap is formed between the sensing beam and the mechanical beam.

### CROSS REFERENCE TO RELATED APPLICATIONS

This application claims the benefit of U.S. Provisional Patent Application No. 61/317,729 filed Mar. 26, 2010, the content of which is hereby incorporated by reference in its entirety.

### FEDERALLY SPONSORED RESEARCH AND DEVELOPMENT

This invention was made with U.S. Government support under contract Number ECCS-747620 awarded by the National Science Foundation. The U.S. Government may have certain rights in the invention.

### BACKGROUND

The development of resonant mass sensors based on cantilever or double-clamped beam structures has undergone rapid progress in the last few years. The operating principle of these sensors is based on the resonant frequency shift induced by a mass change. One trend in this field is that the dimension of the resonators is scaling down to the nanometer regime. Such devices are generally called NEMS (Nano-Electro-Mechanical Systems) resonators. NEMS resonators have achieved very high mass resolution. For example, researchers have demonstrated zepto-gram (10⁻²¹ gram) mass sensing using NEMS resonators. Theoretical analysis indicates that single-Dalton (1 amu) resolution can be achieved by these NEMS resonators.

An issue of NEMS resonators is that the vibration amplitude becomes extremely miniscule. The well-known optical interferometry and optical lever techniques are very sensitive displacement measurement methods for larger MEMS resonators. However, the system is expensive, large, and not readily scalable to arrays of sensors. Furthermore, these methods become insensitive when the dimension enters the nanometer regime due to the diffraction of light. Capacitive sensing, a popular transduction method for MEMS, also becomes ineffective at nanoscale since the capacitance scales down rapidly with the dimension and the motional impedance becomes huge. Magnetomotive transduction has been successfully used for NEMS resonators. But it needs strong magnetic field and thus is not convenient to use. Single Electron Transistor (SET) is another highly sensitive method to measure the displacement, but usually requires low temperature operation.

In view of the above, it is apparent that there exists a need for a displacement transduction method that is low-cost, compact (e.g., on-chip sensing), convenient to use, scalable to large arrays of resonators, and simultaneously is sensitive enough to detect the small motion of NEMS resonators.

### SUMMARY

In spite of these exciting progresses, there are a number of challenges facing NEMS resonators such as the detection of miniscule displacement and operation in liquid, that need to be further addressed. In satisfying the above need, as well as overcoming the enumerated drawbacks and other limitations of the related art, a resonant sensor is provided. The resonant sensor may have a structure including a base portion, a mass portion, and a mechanical beam connecting the base portion to the mass portion. In addition, the structure may include at least one sensing beam formed from a sensing material responsive to mechanical strain where a gap is formed between the sensing beam and the mechanical beam.

In some implementations, a resonant sensor based on piezoresistive asymmetric gapped cantilevers can effectively address these challenges. It is worth noting that piezoresistive sensing is low-cost, on-chip, and scalable to large arrays. However, the major drawback of piezoresistive sensing is its low sensitivity. The asymmetric gapped cantilever structure significantly increases the sensitivity of displacement detection and greatly improves the performance of the resonator. Another explanation of this improvement is that this structure enables the majority of vibrating energy to be used for the generation of output signal. With asymmetric gapped cantilever, the mass resolution of the resonator is considerably improved compared with conventional piezoresistive resonators. For another well-known challenge of resonant mass sensing, e.g., the viscous damping in liquid, integrating microchannels has been demonstrated to be an effective approach. A unique advantage of the asymmetric gapped cantilever is that these channels can be decoupled from the piezoresistors and thus the false signal caused by the temperature or pressure change induced by liquid sample can be minimized. In addition, the asymmetric gapped cantilever enables very efficient on-chip thermal excitation of the resonator, leading to a very compact system.

In accordance with one implementation, a resonant sensor includes a piezoresistive layer and a mechanical layer. The piezoresistive layer has a first section, a second section, and at least one cantilever beam that connects the first section and the second section. The mechanical layer is adjacent the piezoresistive layer and includes a base section, a mass section, and at least one cantilever beam that connects the base section and the mass section. The at least one cantilever beam of the piezoresistive layer and the at least one cantilever beam of the mechanical layer are spaced apart to define an asymmetric gap. This gap may have a height that is approximately equal to the distance between the at least one cantilever beam of the piezoresistive layer and a neutral plane of the asymmetric gapped cantilever.

Other features and advantages will be readily apparent from the following description and from the claims.

### BRIEF DESCRIPTION OF THE DRAWINGS

FIG. 1a is a schematic of the resonator based on piezoresistive asymmetric gapped cantilever (the proof mass is hollow to reduce the effective mass);

FIG. 1b shows a comparison of conventional (top) and asymmetric gapped (bottom) cantilevers;

FIG. 2 shows two deformation modes of the composite asymmetric gapped cantilever;

FIG. 3 is a plot of efficiency η as a function of γ with different C (α=11),

FIG. 4 is a 3D illustration of the resonator with integrated microchannel (not to scale) that is embedded in the mechanical beam and decoupled from the piezoresistor and with two pairs of silicon resistors, one pair being piezoresistors, and the other pair being joule heaters;

FIG. 5 is a schematic illustration of AFM based on piezoresistive asymmetric gapped cantilever;

FIG. 6a is a picture of a meso-scale device with bottom aluminum layer (3 mm×20 mm×3 mm), top PZT layer (3.0 mm×5 mm×0.25 mm), a tapered-shape proof mass, and a gap height of 7 mm;

FIG. 6b shows a frequency response of the resonator in vacuum at a resonant frequency of 10079 Hz;

FIG. 7a shows a vibration amplitude (voltage) of the resonator when alcohol and DI water are sequentially injected;

FIG. 7b shows a vibration amplitude change (referenced to case when the channel was empty) as a function of liquid density;

FIG. 8a is a picture of a silicon-micromachined accelerometer based on piezoresistive asymmetric gapped cantilever;

FIG. 8b is a SEM image of the fabricated accelerometer showing both the top piezoresistors and bottom mechanical beam (the dimension of the top piezoresistive beam is 20 μm×10 μm×2 μm (length×width×thickness) and the bottom mechanical beam is 120 μm×400 μm×50 μm),

FIG. 8c is a magnified view of the top piezoresistor;

FIG. 8d shows the frequency response (in air) of the device under 1 g acceleration;

FIGS. 9a through 9f show a fabrication process of a sensor based on asymmetric gapped cantilever;

FIG. 9a shows a deposit and pattern Au/Cr thin films on the SOI wafer;

FIG. 9b shows a pattern the device layer to form top piezoresistive beams;

FIG. 9c shows a deposit and pattern a parylene layer; strip the exposed oxide layer;

FIG. 9d shows an etch from the front side of the wafer using DRIE;

FIG. 9e shows a DRIE from the back side of the wafer; and

FIG. 9f is a top side view of the finished accelerometer.

### DETAILED DESCRIPTION

Detection of Minuscule Vibration

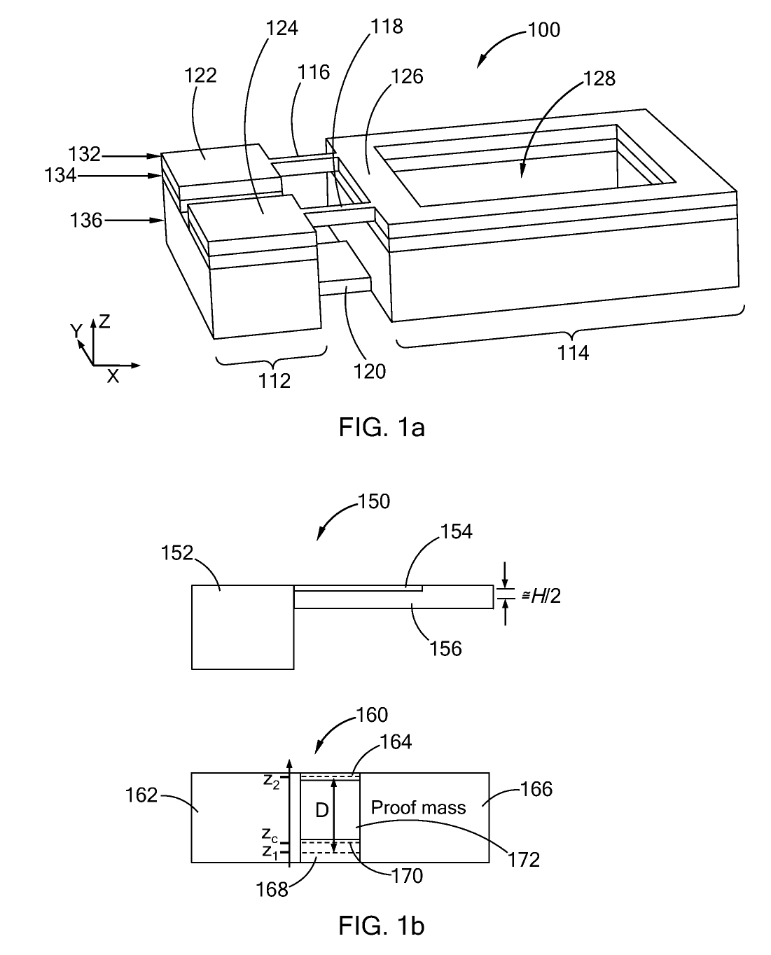

Now referring to FIG. 1a, the resonance sensor 100 is provided. The resonance sensor includes a base section 112 and a mass section 114. Each of the base section 112 and the mass section 114 may be comprised of a plurality of layers including for example, a mechanical layer 136, an insulation layer 134, and a sensing layer 132. The mechanical layer may comprise a silicon, aluminum, other metals, ceramics, various plastics, or other suitable structural materials. The insulation layer 134 may be comprised of oxide, nitride, or other known insulative materials. The sensing layer 132 may be comprised of a piezoresistive material, a piezoelectric material or other functional materials, for example, that are recognized as having a significant change in magnetic or electrical properties based on mechanical strain. In some examples, the electrical properties that may change may include capacitance, inductance, resistance or other known electrical properties. In addition, a mechanical beam 120 may be connected between the base section 112 and the mass section 114. In some implementations, the mechanical beam 120 may be the same material as the mechanical layer 136 of the base section 112 and the mass section 114. Further, it may be preferable if the mechanical beam 120 is integrally formed with the mechanical layer 136 of the base section 112 and the mass section 114.

Further, a first cantilevered beam 116 and a second cantilevered beam 118 of functional material may be connected between the base section 112 and the mass section 114. Although it is understood as described in more detail below that one or more that two beams of functional material may be used. Further, it is also understood that the cantilevered beam of functional material may also be referred to as a sensing beam herein. In some implementations, the cantilevered beams of functional material 116, 118 may be integrally formed with the sensing layer 132 of the base section 112 and the mass section 114. In addition, the cantilevered beams 116, 118 may be a piezoresistive material and as such, may be connected by a conductive section 126 of the mass section 114. A conductive section 126 may be the same material as the cantilevered beams and may be integrally formed with the cantilevered beams 116, 118. However, in some implementations the conductive section 126 may be a separate conductive material provided to form an electrical series connection between the first cantilevered beam 116 and the second cantilevered beam 118. Further, an opening or hole 128 may be formed in the mass section 114 to provide the appropriate physical characteristics of the mass section to optimize the sensing of the resonant sensor due to the mechanical strain introduced into one or more of the cantilevered beams 116, 118. As such, the type of material including density and yield strength, as well as, the size of each section may be carefully selected to provide improved sensing results. As such, the mechanical beam width, thickness, and length will be referred to as w₁, t₁, l₁ respectively. The cantilevered beam dimensions will be referred to as width w₂, thickness t₂, length l₂. Further, the mass dimensions will be referred to as width wₚₘ, thickness tₚₘ, length lₚₘ. For the purposes of this description, the length is being referred to in the X dimension in which the base section 112, cantilevered beams 116, 118, 120 and the mass section 114 are laid end to end, the thickness is shown as the Z dimension is generally the dimension in which the layers 132, 134, 136 are built upon each other. The width dimension is shown as the Y dimension that is perpendicular to both the thickness and length and extends across both of the base section 112 and mass section 114.

For this resonator design, the supporting beam of the proof mass may be an asymmetric gapped cantilever, including a bottom mechanical layer and a top piezoresistive layer separated by a gap as shown in FIG. 1a. Piezoresistivity is a widely used sensing mechanism for silicon-micromachined devices. Piezoresistivity has advantages of low cost, on-chip sensing, simple readout circuits, and excellent scalability for large array sensing. But the low sensitivity of piezoresistivity limits the performance of conventional piezoresistive resonators.

Now referring to FIG. 1b, a side view of a single beam resonant sensor 150 is shown in comparison to another implementation 160 utilizing an asymmetrically gapped multiple beam resonance sensor 160. The sensor 150 includes a base 152, a piezoresistor 154, and a mass section 156. The piezoresistive material 154 is connected directly to a mass section 156. In contrast, the resonant sensor 160 includes a gap 172 between the sensing beam 164 (e.g. functional material such as piezoresistive material) and the mechanical beam 168. Further, the mechanical structure of the sensing beam 164 and the mechanical beam 168 are asymmetric. When discussing that the cantilevered structure, such as, the sensing beam 164 and the mechanical beam 168 are asymmetric this can include that the beams have a different width, thickness, length, and material property, such as density or yield strength, which becomes effective to increase the sensitivity of the resonant sensor due to the gap between the sensing beam 164 and the mechanical beam 168 which will be discussed further herein. In addition, the sensor 160 includes a base 162 and a mass 166 that are connected by the mechanical beam 168.

Further, it may be helpful to note that while the gap is generally considered between the top surface of the mechanical beam 168 and the bottom surface of the sensing beam 164, the distance D, which can be important in selecting parameters for the best solution, is the distance between the middle plane of the sensing beam 164 and the middle plane of the mechanical beam 168. In addition, a neutral plane of the asymmetric gapped cantilever may also be defined as denoted by reference numeral 170. The neutral plane may be understood as the plane at which no stress is introduced independent of the load applied to the structure. This may be a function of the material type and thickness, as well as, other factors. Therefore, it may also be noted that a distance d₂ is the distance between the middle plane of the sensing beam 164 to the neutral plane and a distance d₁ is the distance between a neutral plane and the middle plane of the mechanical beam 168. As such, D=d₁+d₂.

The asymmetric gapped cantilever structure is able to increase the sensitivity by orders of magnitude while maintaining the other advantages of piezoresistive sensing. Referring to the cross sectional views of the conventional cantilever and asymmetric gapped cantilever shown in FIG. 1b, for both cantilevers, the mechanical strain experienced by the piezoresistor is proportional to the distance between the piezoresistor and the neutral plane. The difference is that for the asymmetric gapped cantilever, the distance D is approximately equal to the height of the gap between the top and bottom beams, whereas for conventional cantilever, this distance is only half of the cantilever thickness H/2, which is much smaller. Therefore, the asymmetric gapped cantilever sensor improves the sensitivity by orders of magnitude.

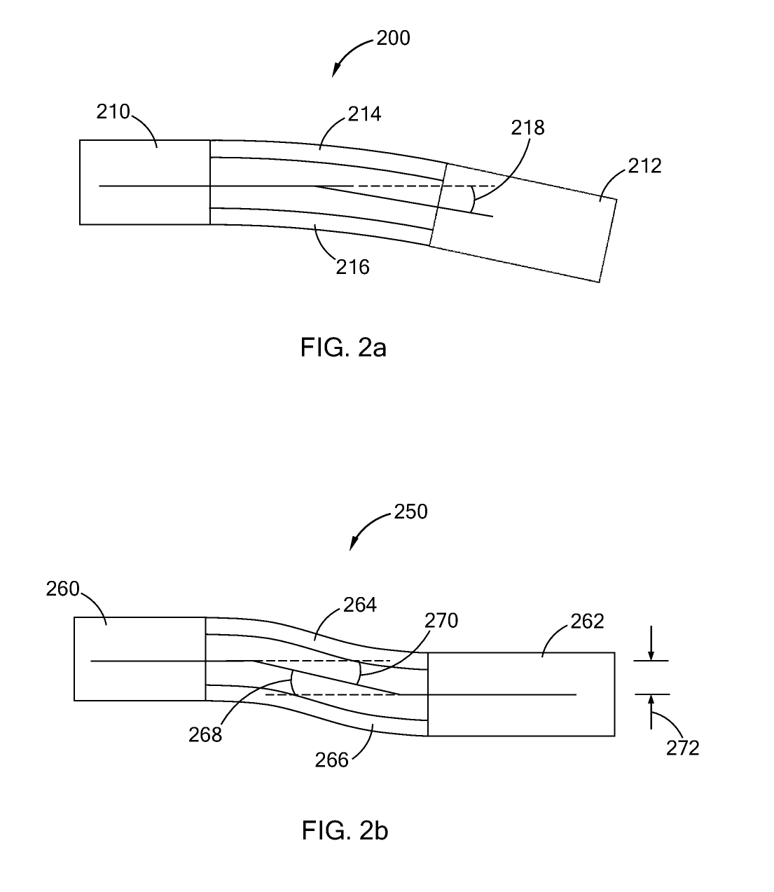

Now referring to FIG. 2, an asymmetrically gapped cantilever sensor 200 is illustrating under pure bending. As such, the mass portion 212 is rotated with respect to the base portion 210 causing bending in both the sensing beam 214 and the mechanical beam 216. The bending of the sensing beam 214 and the mechanical beam 216 may be illustrated by angle 218. FIG. 2b illustrates an asymmetrically gapped cantilever sensor 250 in an S shaping mode. Accordingly, the mass section 216 may be translated with respect to the base section 260. This translation is illustrated by reference numeral 272. Further, this may cause multiple bends or a gradiation of bending in the sensing beam 264 and the mechanical beam 266. This gradiation of bending may be illustrated by angles 270 and 268 in FIG. 2b.

An analytical model for the asymmetric gapped cantilever has been developed. Unlike a conventional cantilever, the deformation of the asymmetric gapped cantilever is considered in both pure bending (rotational movement) and S-shaping modes (translational movement) (FIGS. 2a and 2b). Obviously, the plane assumption is not valid anymore and conventional Euler-Bernoulli beam theory cannot be applied here.

The bending rigidities for pure bending and S-shape bending R_{P} and R_{S} are given by:

$$\begin{matrix}{R}_{P} = {E}_{1} ( \frac{{w}_{1} {t}_{1}^{3}}{12} + {( {z}_{1} - {z}_{c} )}^{2} {w}_{1} {t}_{1} ) + {E}_{2} ( \frac{{w}_{2} {t}_{2}^{3}}{12} + {( {z}_{2} - {z}_{c} )}^{2} {w}_{2} {t}_{2} ) & ( 1 ) \\ {R}_{S} = {E}_{1} \frac{{w}_{1} {t}_{1}^{3}}{12} + {E}_{2} \frac{{w}_{2} {t}_{2}^{3}}{12} & ( 2 )\end{matrix}$$

where z₁, z₂ and z_{c} are the vertical coordinates (please refer to FIG. 1b) of the bottom mechanical beam, top sensing beam and neutral plane. E₁ and E₂ are Young's moduli, of the bottom mechanical beam and top sensing beam, respectively. The spring constants of the two modes are:

$${k}_{P} = \frac{4 {R}_{S}}{{l}^{3}} \frac{1}{{α}^{2} β} and {k}_{S} = \frac{12 {R}_{S}}{{l}^{3}} \qquad ( 3 ) and ( 4 )$$

where α=(l+lₚₘ)/l and β=R_{S}/R_{P}. The normal strain experienced by the top sensing beam is:

$${ɛ}_{2} = \frac{F ( l + {l}_{pm} ) {d}_{2}}{2 {R}_{P}} \qquad ( 5 )$$

where F is the inertial force applied and d₂ is equal to z₂−z_{c}. It can be observed that the normal strain of the sensing beam is proportional to d₂, the distance between the top sensing beam and the neural plane of the asymmetric gapped cantilever. This distance is approximately equal to the height of the gap for asymmetric gapped cantilevers and can be fairly large. Therefore, the asymmetric gapped cantilever provides a very high displacement sensitivity.

From an energy point of view, it is desirable to allocate as much energy as possible for strain sensing from the total energy applied. Note that the vibration energy is stored in different forms. However, only the energy stored in the top sensing layer in the form of normal strain is effective in generating output voltage. Here the energy efficiency η is defined as the ratio of the energy stored by normal strain of the top sensing layer to the total mechanical energy, which can be calculated in two steps. First, the ratio of the energy stored by pure-bending to the total energy can be easily derived from spring constant equations, which is:

$${η}_{1} = \frac{{k}_{S}}{{k}_{P} + {k}_{S}} = \frac{1}{1 / 3 {α}^{2} β + 1} \qquad ( 6 )$$

Then the pure bending energy is distributed in both top and bottom beams. The percentage of pure bending energy stored in the top sensing layer in the form of normal stain is:

$${η}_{2} = \frac{{E}_{2} {w}_{2} {{t}_{2} ( {z}_{2} - {z}_{c} )}^{2}}{{R}_{P}} = ( 1 - β ) ( 1 - γ ) \qquad ( 7 )$$

where γ=(z_{c}−z₁)/D=d₁/D. Therefore, the total percentage of the vibration energy used for strain sensing is:

$$η = {η}_{1} {η}_{2} = \frac{( 1 - β ) ( 1 - γ )}{1 / 3 {α}^{2} β + 1} \qquad ( 8 )$$

The optimal γ that results in the maximum efficiency is:

$${γ}_{o} = \frac{1}{1 + \sqrt{1 + \frac{1}{C} + \frac{1 + C}{{C}^{2} ( 3 {α}^{2} + 1 )}}} \qquad ( 9 )$$

where C=t₁²/12D².

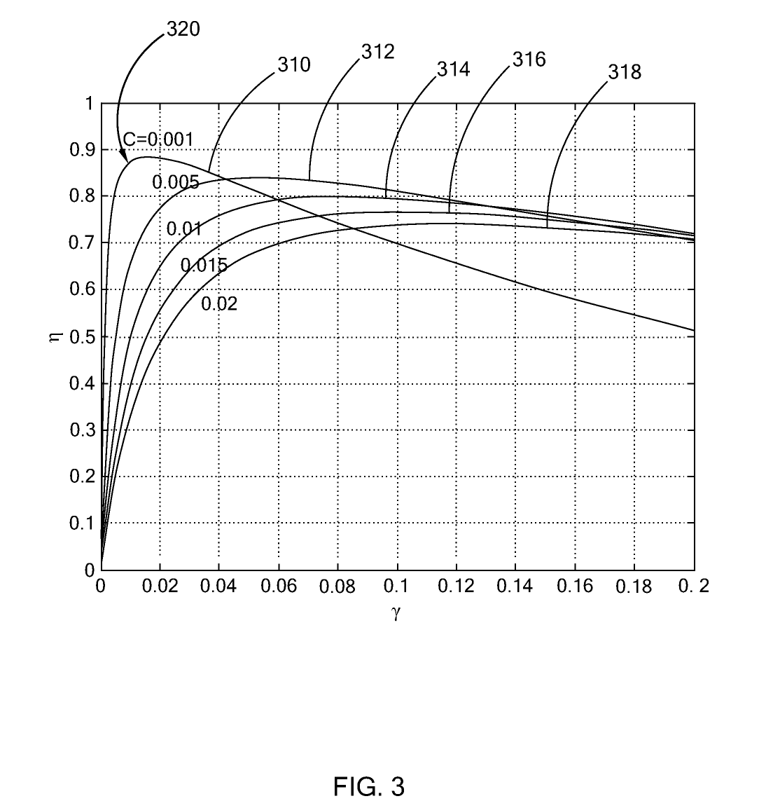

Now referring to FIG. 3, a plot of efficiency as a function of γ is provided for different values of C, where α is kept constant at 11. Line 310 illustrates the function with a value for C of 0.001, line 312 illustrates the function for a value for C of 0.005, line 314 illustrates the function for a value for C of 0.01, line 316 illustrates the function for a value for C of 0.015, and line 318 illustrates the function for a value for C of 0.02. Further, the peak as denoted by arrow 320 illustrates that a significant increase of sensing can be obtained using this combination of parameters.

The plot of efficiency η as a function of γ with different C values may be helpful in selecting other related parameters. Once γ₀ has been decided, the distance between neutral plane and top sensing beam d₂, and other related parameters such as w₁, w₂ and t₂ can be determined.

It can be observed that the design allows the majority of the vibration energy to be used to strain the piezoresistors. But for the conventional cantilever, most of the energy is wasted to strain the non-sensing layer because the volume of the piezoresistor is only a small portion of the total cantilever. Therefore, from an energy point of view, the asymmetric gapped cantilever is a much more efficient design.

When the design is optimized, the spring constant is approximately given by:

$$k \approx {k}_{P} \approx \frac{4 {E}_{2} {w}_{2} {t}_{2} {d}_{2}^{2}}{{l ( l + {l}_{pm} )}^{2}} \qquad ( 10 )$$

It is very intriguing and even counter-intuitive to note that the equivalent spring constant of the cantilever is actually dominated by the top sensing beam, which is much smaller than the bottom mechanical beam. This implies that during vibration, the majority of mechanical energy is stored in the top sensing layer, although the bottom mechanical beam is actually much larger. This is because the bottom mechanical beam serves as a hinge which allows rotational movement of the proof mass but constrains the translational movement. Consequently, for the rotational movement of the proof mass, which is the desirable mode, the top smaller sensing beam plays the dominant role. An implication of this result is that a small variation of the dimension or mechanical properties of the bottom mechanical beam will not affect the performance of the resonator significantly.

Operation in Liquid

It is worth noting that most of those impressive results reported so far such as zepto-gram mass resolution were achieved in very high vacuum which helps to maintain the high quality factor of resonating. However when operated in liquid, which is the case for many bio/chemical sensing applications, the viscous damping will decrease the quality factor of the resonator, and thus degrade the performance significantly. This issue is well-known in this community and many efforts are underway to overcome or circumvent this problem. Burg et al. demonstrated a method by integrating microfluidic channels with cantilever resonators. With this approach, the solution flows inside the resonator, considerably reducing the viscous damping. The quality factor (˜15,000) of the resonator was not reduced significantly after the microchannel was filled with water.

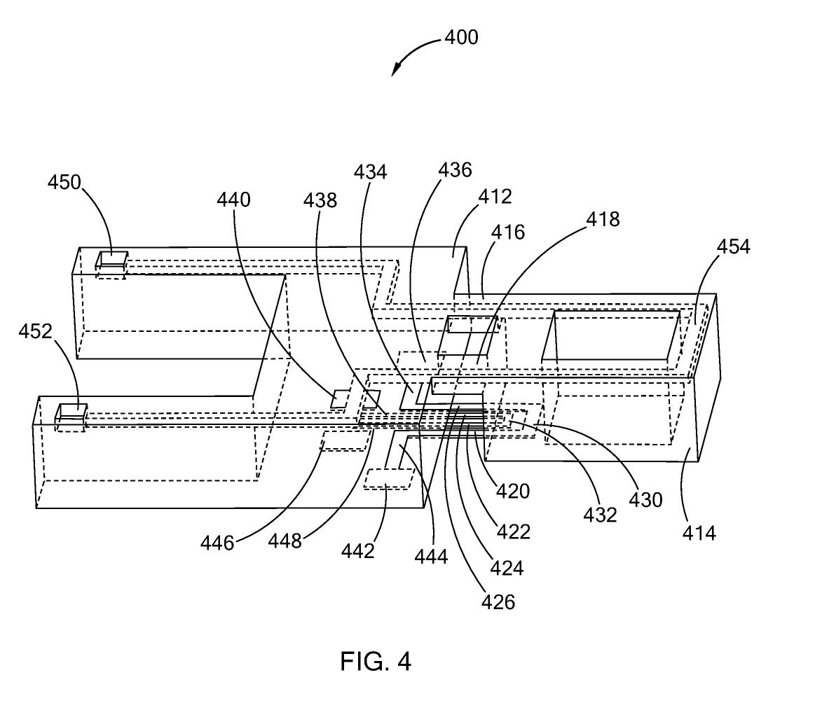

The asymmetric gapped cantilever provides a unique advantage. One problem of this microchannel approach for conventional cantilever is that the introduced fluid in the channel usually changes the mechanical property of the resonator (e.g., via temperature or pressure change induced by the fluid) and leads to false signals. But for the asymmetric gapped cantilever, the channel is embedded in the mechanical beam, separated from the piezoresistors as schematically shown in FIG. 4. Therefore, the false signals caused by the liquid flow are minimized since the resonant frequency is mainly determined by the top piezoresistive beams (as shown in Eq. 10) which are de-coupled from the channel.

Now referring to FIG. 4, an asymmetrical gapped resonating sensor 400 is provided. The sensor 400 includes a base section 412 and a mass section 414. In addition, two mechanical beams 416 and 418 are connected between the base section 412 and the mass section 414. However, it is understood that a single mechanical beam may be utilized. In addition, a first sensing beam 426 and a second sensing beam 420 may be provided between the base section 412 and the mass section 414. As previously denoted, in earlier discussions, the sensing beams 426 and 420 may be formed of functional material. A first heater 424 and a second heater 422 may also be provided between the base section 412 and the mass section 414. To complete the circuit between the first heater and second heater, a conductive section 432 may be provided. In a similar manner and as discussed previously above, a conductive section 430 may be provided between the first sensing beam 426 and the second sensing beam 420 to complete the circuit between the functional materials (e.g. piezoresistive or piezoelectric materials). Although, it is understood that a single sensing beam may be utilized in some implementations where both beams are not necessary such as with a piezoelectric material where a voltage is created due to strain. The first sensing beam 426 may be connected to a pad 436 by a trace 434. The pad and the trace may be formed of conductive material and in some implementations may be formed of the same material as the sensing beam 426. Similarly, the sensing beam 426 may be connected to pad 442 by trace 444. In addition, the first heater 424 may be connected to pad 440 to trace 438 and the second heater 422 may be connected to pad 446 through trace 448. In addition, a channel 454 may be formed in the mass section 414. An input port 450 and an output port 452 may be provided in the base section 412. As such, the channel 454 may extend from the input port 450 through one or more of the mechanical beams 416, 418 and into the base section 414. Further, the channel 454 may extend around the periphery of the base section 414, for example, in a symmetric manner and then extend back through one of the mechanical beams 416, 418 into the base section 412 and to the output port 452.

Actuation of NEMS Resonator

As the dimension scales down and resonant frequency scales up, the actuation of a NEMS resonator is becoming a challenging task as well. Thermal actuation (joule heating) has been demonstrated to be effective in driving MEMS/NEMS resonators. This method has advantages of low-cost, easy on-chip integration, low-voltage operation, individual control of resonators, etc. For the asymmetric gapped cantilevers, this actuation mechanism can be easily implemented by fabricating another pair of silicon resistors in parallel with the sensing piezoresistors, for example as shown in FIG. 4. There are several unique advantages of using thermal excitation for asymmetric gapped cantilevers. First, the asymmetric gapped cantilever provides a much more efficient way of thermal actuation. For conventional cantilevers, the actuation is usually caused by the difference of thermal expansion coefficients of two materials. As a result, a large amount of energy is wasted. For the asymmetric gapped structure, almost 100% of the thermal expansion of the heater is used to drive the resonator. Second, the heating resistors are very short and free-standing. Therefore, very fast thermal actuation is achieved since only the heater itself needs to be heated up.

When a voltage V_{act}=V_{dc}+V_{ac} sin ωt is applied to a free-standing resistor bridge, the temperature distribution is approximately parabolic and the average temperature increment is:

$$Δ T = \frac{{V}_{dc}^{2} + 0.5 + 2 {V}_{dc} {V}_{ac} sin ω t - 0.5 {V}_{ac}^{2} cos 2 ω t}{12 {k}_{th} {ρ}_{e}} \qquad ( 11 )$$

where kₜₕ is thermal conductivity (silicon: 119 W/m·K at 350K), and ρₑ is electrical resistivity. Neglecting the DC and 2ω components, the strain experienced by the piezoresistor is:

$$\begin{matrix}ɛ \approx g {α}_{th} Δ T ( ω ) \\ = \frac{g {α}_{th} {V}_{dc} {V}_{ac} sin ω t}{6 {k}_{th} {ρ}_{e}} \frac{1}{1 + jω / {ω}_{th}} \frac{1}{1 - {( ω / {ω}_{0} )}^{2} + jϖ / {ω}_{0} Q}\end{matrix} \qquad ( 12 )$$

where g is the ratio of the heater width to overall width (heater+piezoresistor), αₜₕ is the thermal expansion coefficient (silicon: ˜3×10⁻⁶/k at 350 K), ωₜₕ is the thermal cutoff frequency, and Q is the quality factor. Note that the expression consists of three terms. The first term is the strain that occurs at DC or low frequency due to thermal expansion. The second term, which is a transfer function of a low pass filter, accounts for the effect of thermal time constant. Namely, when the voltage applied is too fast, the temperature change may not be able to catch up the rate of voltage change. The last term represents the mechanical response of the resonator (a second-order spring-mass system). It can be easily observed that at ω₀, the mechanical strain is amplified by Q times.

For conventional thermal actuation, ωₜₕ is usually much smaller than the mechanical resonant frequency ω₀. Therefore, there is considerable attenuation due to the slow thermal response. Thermal actuation still can be used due to the large mechanical gain at ω₀. However, the efficiency is low.

For the asymmetric gapped cantilever, the heater is a free-standing resistor and the thermal time constant τ is given by:

$$τ = \frac{{l}^{2} ρ c}{8 {k}_{th}} \qquad ( 13 )$$

where ρ is density (silicon: 2330 kg/m³), c is specific heat (silicon: 710 J/kg·K), and l is the heater length. Because of the small and very short heater length, the thermal cutoff frequency is much higher and is closer to the mechanical resonant frequency. Consequently, the attenuation due to thermal time constant is not significant. The asymmetric gapped cantilever structure enables very fast and efficient thermal actuation.

It is worth noting that the resonator based on piezoresistive asymmetric gapped cantilever can serve as a generic platform for a wide range of applications. In addition to mass sensing, the resonator can be used for resonant-mode atomic force microscope (AFM). Because of piezoresistive sensing, such AFM will be low-cost, miniaturized, portable and large arrays of cantilevers can be integrated for high-throughput parallel scanning. The resonator can also serve as a frequency reference or high-Q component for RF circuits. It is also worth noting that the piezoresistive sensing element can be replaced by other functional materials such as piezoelectric material, whereas the advantages of asymmetric gapped cantilever remain.

Atomic Force Microscope (AFM) Based on Asymmetric Gapped Cantilever

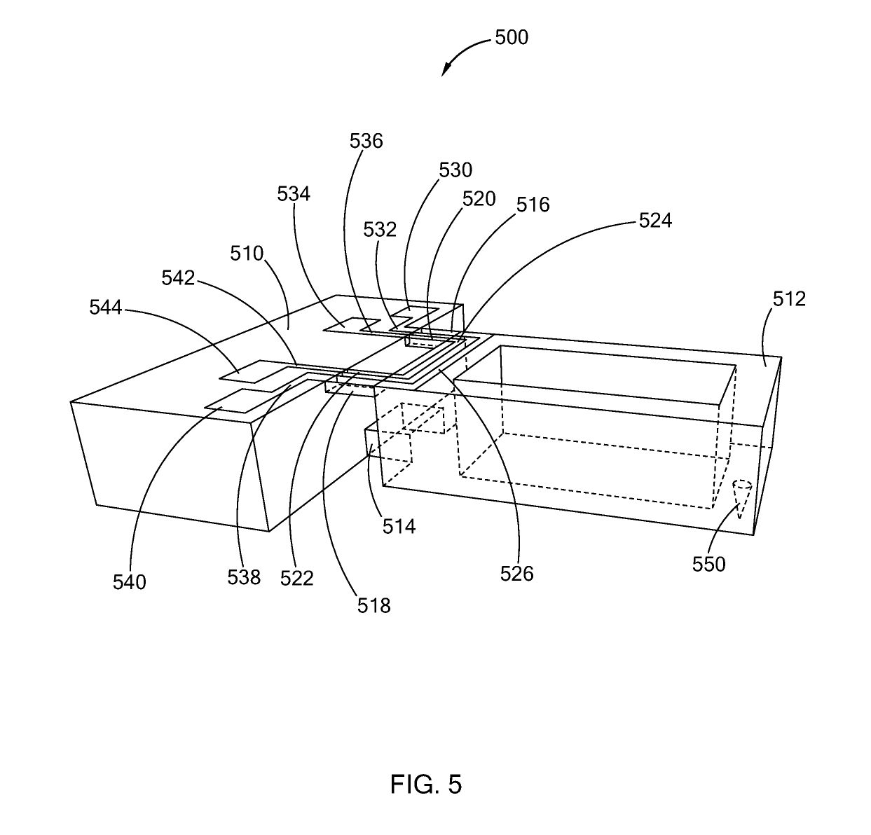

FIG. 5 is a schematic illustration of AFM developed based on piezoresistive asymmetric gapped cantilever. A pair of heaters is also integrated for on-chip thermal actuation. The displacement sensitivity is:

$${S}_{Z} = \frac{Δ R}{R} \cdot \frac{{V}_{in}}{Z} = \frac{6 {π}_{l} {E}_{2} {α}^{′} β {d}_{2}}{3 ( {α}^{′ 2} β + 1 ) {l}^{2}} {V}_{in} \qquad ( 14 )$$

where πₗ is the longitudinal piezoresistance coefficient, α′=(l+2lₚₘ)/l, and Vᵢₙ is the voltage across the piezoresistor. The force sensitivity can be expressed as:

$${S}_{F} = \frac{Δ R}{R} \cdot \frac{{V}_{in}}{F} = \frac{{π}_{l} {E}_{2} {α}^{′} {ld}_{2}}{2 {R}_{p}} {V}_{in} \qquad ( 15 )$$

Where R is resistance and F is force. For slope detection method, the minimum detectable force gradient is given by:

$${F}_{min}^{′} \approx \frac{\sqrt{27} k {〈 {v}_{n}^{2} 〉}^{1 / 2}}{2 Q {〈 {z}_{Osc}^{2} 〉}^{1 / 2} {S}_{Z}} \qquad ( 16 )$$

where Z_{Osc} is oscillation amplitude, vₙ is noise voltage. The asymmetric gapped cantilever has a significantly increased displacement sensitivity. Therefore, the AFM performance is greatly improved.

The minimum detectable force gradient can also be expressed as:

$${F}_{min}^{′} \approx \frac{\sqrt{27 k}}{2 Q {〈 {z}_{Osc}^{2} 〉}^{1 / 2}} \sqrt{\frac{〈 {v}_{n}^{2} 〉}{{S}_{Z} {S}_{F}}} \qquad ( 17 )$$

For Johnson noise dominated case,

$$\frac{{S}_{z} {S}_{f}}{〈 {v}_{n}^{2} 〉} = \frac{{π}_{l}^{2} {E}_{2} {V}_{in}^{2}}{16 {k}_{B} T ρ ( {f}_{max} - {f}_{min} )} \cdot \frac{1}{{l}^{2}} \cdot \frac{{k}_{s}}{{k}_{p} + {k}_{s}} \cdot \frac{{E}_{2} {A}_{2} {d}_{2}^{2}}{{R}_{p}} ∝ η \qquad ( 18 )$$

Which is proportional to the energy efficiency η. As explained previously, the asymmetric gapped structure has a nearly 100% energy efficiency.

In FIG. 5, the asymmetric gapped resonator sensor is indicated by reference numeral 500. The sensor 500 includes a base section 510 and a mass section 512. As discussed in other embodiments, the sensor 500 may include a mechanical beam 514 connecting the base section 510 to the mass section 512. In addition, one or more cantilevered beams of functional material, for example, piezoresistive beam 516 and piezoresistive beam 518. The circuit may be formed between pad 530 and pad 540 such that the change in resistance may be measured between the two pads. As such, the pad 530 may be connected to piezoresistive beam 516 through trace 532. Further, piezoresistive beam 516 may be connected to piezoresistive beam 518 through trace 526. Finally, piezoresistive beam 518 may be connected to pad 540 through trace 538. In a similar manner, a circuit may be formed between pad 534 and pad 544 through resistors 520 and 522. Pad 534 may be connected to resistor 520 through trace 536, while resistor 520 may be connected to resistor 522 through trace 524. Heater 522 may be connected to pad 544 through trace 542.

As previously discussed, any of the traces or pads may be formed of the same functional material as the cantilevered beams 516, 518 or the resistive heated material 520, 522. However, in some embodiments, some or all of the traces and pads may be formed from a conductive material that is different from the resistive heaters and/or the piezoresistive cantilevered beams. A voltage may be provided between pads 534 and pad 544 to actuate the heaters and facilitate resonance of the sensor. In addition, a voltage measurement device may be connected between pads 530 and 540 to sense the electrical change in cantilevered beams 516, 518. In addition, a pointed tip 550 may be provided on one end of the mass, for example, at an opposite end of the mechanical beam 514 to aid in producing a mechanical strain in the cantilevered beams 516, 518.

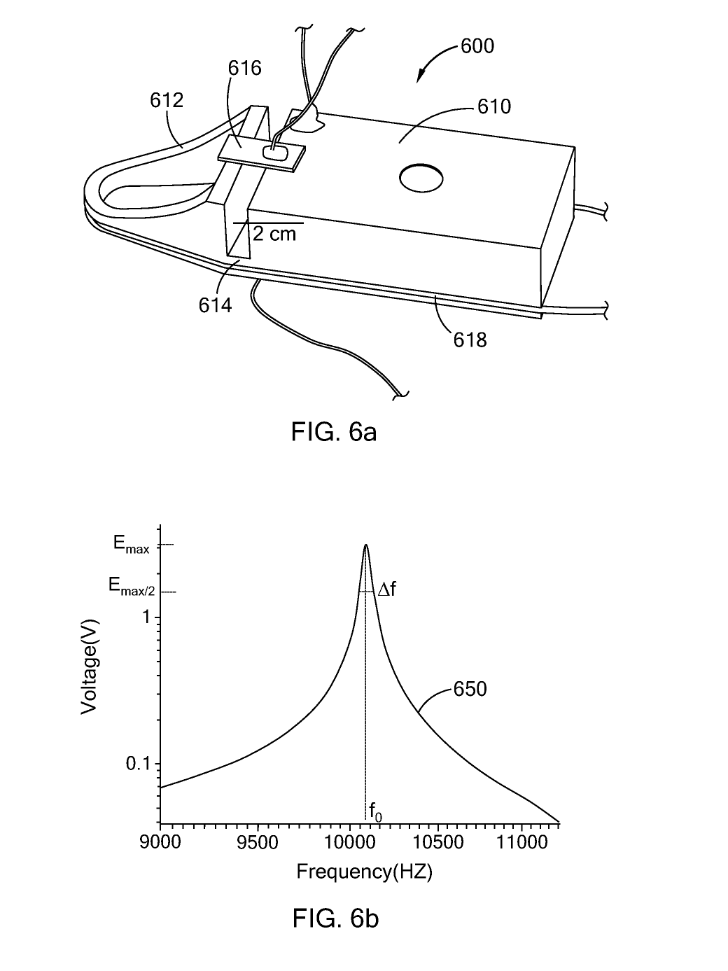

A meso-scale version of the resonant sensor based on the asymmetric gapped cantilever has been developed and tested. The sensor body was machined using an aluminum block and a PZT (Lead zirconate titanate) sheet (T105-A4E-602, Piezo System, Inc., Cambridge, Mass., USA) was employed as the sensing layer. The resulting asymmetric gapped cantilever with the PZT plate bonded across the trench is shown in FIG. 6 (a). A PEEK tubing (0.020 in. i.d.) was glued to the sidewall of the resonator. Another PZT sheet was bonded to the bottom surface of the aluminum mechanical beam to drive the resonator. The hollow and tapered shape of the proof mass was machined for a smaller effective mass.

In FIG. 6a, the asymmetric gapped resonant sensor is identified as reference numeral 600. The sensor 600 includes a base portion 610 and a mass 612. A mechanical beam 614 is connected between the base section 610 and the mass section 612. In addition, a cantilevered beam 616 may be provided between the base section 610 and the mass section 612 in this implementation, the cantilevered beam 616 is a piezoelectric material although it is understood that other functional material may be used as described in the previous implementations. A small tube 618 is connected to the sensor 600 and may extend from the base section 610 along the mechanical beam 614 and around the periphery of the mass section 612. The tube 618 may then travel back across the mechanical beam 614 to the base section 610 allowing fluid to flow through the tube and around the periphery of the mass section 612 for sensing purposes.

In FIG. 6b, the voltage response of the sensor 600 is provided with respect to frequency, as denoted by line 650. The graph illustrates that a resonant frequency of 10079 Hz is observed and the quality factor is about 240.

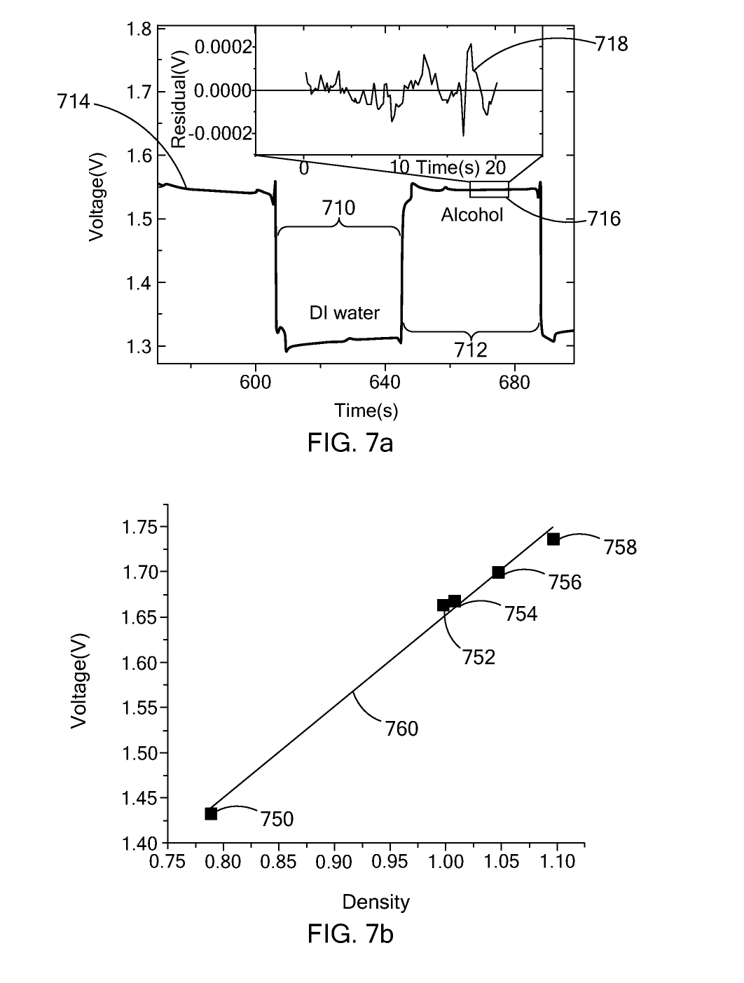

This version was tested by sequentially injecting alcohol and DI water in the PEEK tubing. In our preliminary test, the resonator was driven at a fixed frequency slightly higher than its resonant frequency. The shift of resonant frequency was measured indirectly through the amplitude change of the vibration (slope detection). FIG. 7a shows the real-time amplitude change of the resonator when alcohol and DI water were sequentially injected. The signal change caused by the different densities of the solution can be clearly observed. The standard deviation of the signal is 6.6×10⁻⁵ V with 5 Hz bandwidth. In FIG. 7a, a graph illustrating the voltage response from the sensor 600 is provided with respect to time as denoted by line 714. Time period 710 illustrates the voltage provided by the sensor 600 when the ionized water flows through the tube 618. Time period 712 corresponds to the time period where alcohol flows through the tube 618. In addition, a portion 716 of the signal 714 is identified as the alcohol flows through the tube 618. As such, the residual information is provided at a higher scale as indicated by line 718 during portion 716, thereby illustrating the residual voltage with respect to time.

The sensor was also tested with 1×, 5×, and 10× phosphate buffer saline (PBS) solutions. The results are summarized in FIG. 7 (b). In FIG. 7b, the voltage of various fluids are shown with respect to the fluid density. Alcohol is denoted by reference numeral 750 and de-ionized water is denoted by reference numeral 752. In addition, 1×PBS is denoted by reference numeral 754, while 5×PBS is denoted by reference numeral 756 and 10×PBS is denoted by reference numeral 758. Accordingly, a linear correlation 760 may be derived for the voltage with respect to the fluid density.

The minimum detectable mass change is 3.5 μg. Note that this is an un-optimized prototype and the noise is larger than expected due to the non-ideal experimental condition. Even based on this non-ideal result, a simple scaling analysis indicates that zepto-gram mass resolution can be achieved if the dimension of the resonator is scaled down by a factor of 1000 (to ˜20 μm).

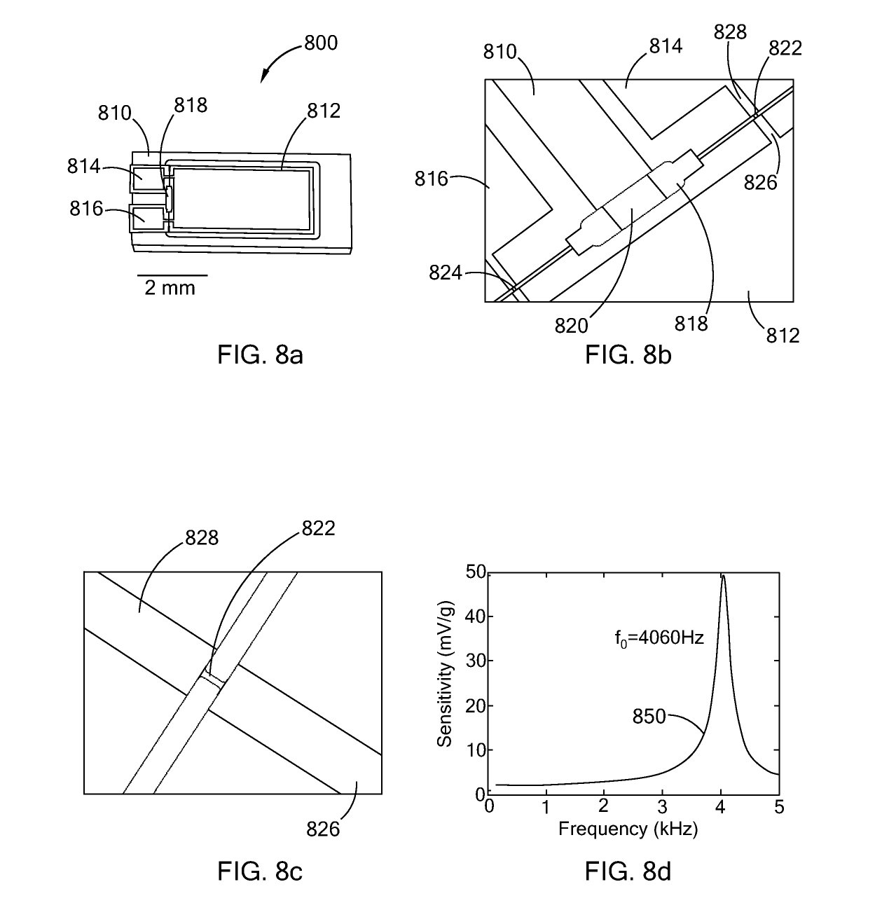

The microfabrication of the piezoresistive asymmetric gapped cantilever on SOI wafer has also been successfully demonstrated recently in the development of a high-sensitivity accelerometer. FIG. 8a shows the picture of one fabricated accelerometer. SEM images showing the details of the asymmetric gapped cantilever and one top piezoresistor are given in FIGS. 8b and 8c.

Now referring to FIG. 8a-c, an asymmetric gapped resonant sensor is shown at various magnifications. The sensor 800 as described in previous implementations may include a base section 810 and a mass section 812. In addition, pads 814 and 816 may be provided for transferring the sensor signal. In addition, an opening 818 is provided that forms the gap between the cantilevered sensing beams and the mechanical beam.

Now referring to FIG. 8b, a view of the sensing beams 824 and 822 are provided at 100× magnification. Pads 814 and 816 are located on the base section 810 and may be connected to the mass section 812 through the traces and sensing beams, for example, pad 814 is connected to the mass portion 812 through the series connection of trace 828, sensing beam 822 and trace 826.

Now referring to FIG. 8c, a 500× magnification image is provided illustrating trace 824, cantilevered beam 822, and trace 826.

The fabricated piezoresistive accelerometer was tested using a mechanical shaker and a commercial accelerometer. A Wheatstone bridge circuit with 5 V supply voltage was used. Now referring to FIG. 8d, a graph of the sensitivity of asymmetric gap resonant sensor 800 is provided with respect to frequency. As such, line 850 properly denotes the relationship between the sensitivity and frequency for sensor 800.

A resonant frequency of about 4.06 kHz was measured, matching with the analytical and simulation results very well (4.10 and 4.15 kHz, respectively).

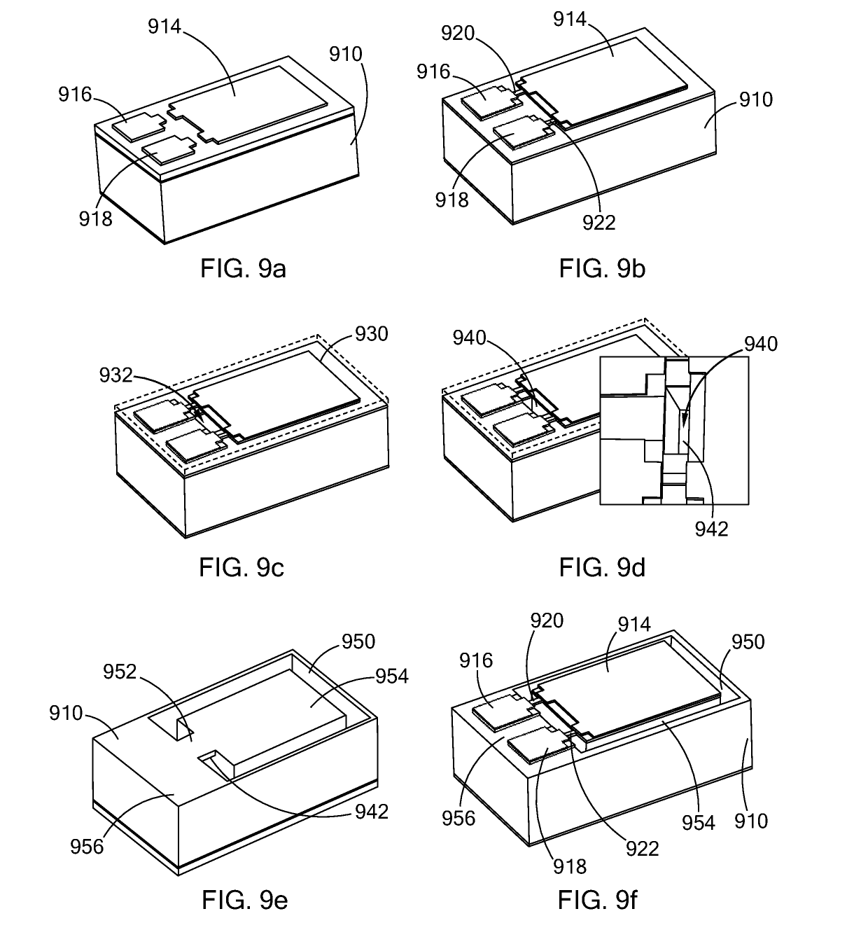

Now referring to FIG. 9a-f, a process is illustrated for manufacturing an asymmetric gap resonant sensor. The fabrication process shown may be carried out on SOI wafers 910. First, a Au thin film is deposited by E-beam evaporation with Cr adhesion layer. This metal layer is then patterned to form the metal traces 914 and contact pads 916, 918, as shown in FIG. 9a. In the next step, with a photoresist mask, DRIE is used to etch the device layer to form the top piezoresistive beams 920, 922 (or heaters, or piezoelectric beams, or other functional cantilever beams), as shown in FIG. 9b. In order to protect the sensor from shocks while handling and packaging, a parylene C layer 930 is deposited on the front side of the wafer. This parylene layer is patterned and etched by oxygen plasma using a thick photoresist mask layer. An etching window 932 for the bottom mechanical beam is opened in this step, as shown in FIG. 9c. The exposed SiO₂ is subsequently stripped by Buffered HF (BHF). Next, DRIE was carried out on the front side of the wafer to etch the exposed area. The inset in step 9d shows a magnified view of the cavity 940 etched. The etching stops when the remaining Si thickness reaches the desirable value. Then the second DRIE is carried out from the back side of the wafer to form an opening 950. A top surface of the remaining Si is indicated by reference number 942. The bottom mechanical beam 952 is first shaped during this etching. This also forms the base section 956 and the mass section 954. The DRIE continues and stops when the buried SiO₂ is reached. The SiO₂ layer is then removed by BHF.

For additional information on the area of practice the following references are noted and incorporated herein by reference in their entirety:
[1] Y. T. Yang, C. Callegari, X. L. Feng, K. L. Ekinci, and M. L. Roukes, “Zeptogram-scale nanomechanical mass sensing,” Nano Letters, vol. 6, pp. 583-586, April 2006.
[2] T. P. Burg, M. Godin, S. M. Knudsen, W. Shen, G. Carlson, J. S. Foster, K. Babcock, and S. R. Manalis, “Weighing of biomolecules, single cells and single nanoparticles in fluid,” Nature, vol. 446, pp. 1066-1069, Apr. 26, 2007.
[3] D. Westberg, O. Paul, G. Andersson, and H. Baltes, “A CMOS-compatible fluid density sensor,” Journal of Micromechanics and Microengineering, vol. 7, pp. 253-255, September 1997.
[4] D. Sparks, R. Smith, M. Straayer, J. Cripe, R. Schneider, A. Chimbayo, S. Anasari, and N. Najafi, “Measurement of density and chemical concentration using a microfluidic chip,” Lab on a Chip, vol. 3, pp. 19-21, 2003.
[5] Q. L. Zheng and Y. Xu, “Asymmetric air-spaced cantilevers for vibration energy harvesting,” Smart Materials & Structures, vol. 17, October 2008.
[6] T. M. Squires, R. J. Messinger, and S. R. Manalis, “Making it stick: convection, reaction and diffusion in surface-based biosensors,” Nature Biotechnology, vol. 26, pp. 417-426, April 2008.
[7] S. Son, W. H. Grover, T. P. Burg, and S. R. Manalis, “Suspended microchannel resonators for ultralow volume universal detection,” Analytical Chemistry, vol. 80, pp. 4757-4760, June 2008.
[8] I. Bargatin, I. Kozinsky, and M. L. Roukes, “Efficient electrothermal actuation of multiple modes of high-frequency nanoelectromechanical resonators,” Applied Physics Letters, vol. 90, 2007.
[9] T. Volden, M. Zimmermann, D. Lange, O. Brand, and H. Baltes, “Dynamics of CMOS-based thermally actuated cantilever arrays for force microscopy,” Sensors and Actuators a-Physical, vol. 115, pp. 516-522, Sep. 21, 2004.
[10] H. T. Yu, X. X. Li, X. H. Gan, Y. J. Liu, X. Liu, P. C. Xu, J. G. Li, and M. Liu, “Resonant-cantilever bio/chemical sensors with an integrated heater for both resonance exciting optimization and sensing repeatability enhancement,” Journal of Micromechanics and Microengineering, vol. 19, April 2009.
[11] Y. Li, Q. Zheng, Y. Hu, and Y. Xu, “Micromachined piezoresistive accelerometers based on an asymmetrically-gapped cantilever,” submitted to Journal of Microelectromechanical Systems.

1. A resonant sensor comprising:
a structure including a base portion, a mass portion, and a mechanical beam connecting the base portion to the mass portion;
a first sensing beam formed from a sensing material responsive to mechanical strain;
a gap being formed between the sensing beam and the mechanical beam.

2. The resonant sensor according to claim 1, wherein the first sensing beam is formed from a piezoresistive material.

3. The resonant sensor according to claim 1, wherein the first sensing beam is formed from a piezoelectric material.

4. The resonant sensor according to claim 1, wherein the thickness of the first sensing beam is different than the thickness of the mechanical beam.

5. The resonant sensor according to claim 1, wherein the width of the first sensing beam is different than the width of the mechanical beam.

6. The resonant sensor according to claim 1, wherein the material of the first sensing beam is different than the material of the mechanical beam.

7. The resonant sensor according to claim 1, wherein the resonant sensor comprises a plurality of sensing beams including the first sensing beams and a number of sensing beams is different than a number of mechanical beams.

8. The resonant sensor according to claim 1, further comprising a second sensing beam formed from a sensing material responsive to mechanical strain.

9. The resonant sensor according to claim 1, wherein the first sensing beam and the second sensing beam are in electrical series connection.

10. The resonant sensor according to claim 1, further comprising at least one heater extending between the base section and the mass section configured to drive the resonator.

11. The resonant sensor according to claim 1, wherein the at least one heater is formed from the sensing layer.

12. The resonant sensor according to claim 1, wherein the relationship of the sensing beam and the mechanical beam is defined by the following relationship
$${γ}_{O} = \frac{1}{1 + \sqrt{1 + \frac{1}{C} + \frac{1 + C}{{C}^{2} ( 3 {α}^{2} + 1 )}}}$$
where C=t₁²/12D², γ=(z_{c}−z₁)/D=d₁/D, and α=(l+lₚₘ)/l, t₁ being the thickness of the mechanical beam, D being the distance between a middle plane of the sensing beam and a middle plane of the mechanical beam, z_{c} being the location of the neutral plane, y₁ being the location of the middle plane of the mechanical beam, d₁ being the distance between the neutral plane and the middle plane of the mechanical beam, l being the length of the mechanical beam, and lₚₘ being the length of proof mass.

13. A resonant mode atomic force microscope incorporating the resonant sensor of any of the previous claims for sensing displacement.

14. The resonant sensor according to claim 1, wherein resonant sensor is incorporated into a densitometer, particle sensor, or biosensor.

15. The resonant sensor according to claim 1, further comprising a channel formed in the mass section for receiving a sample.

16. The resonant sensor according to claim 1, wherein the channel decouples the sample from the sensing beam thermally.

17. The resonant sensor according to claim 1, wherein the channel decouples the sample from the sensing beam mechanically.

18. The resonant sensor according to claim 1, wherein the channel extends through the mechanical base and includes an input port and an output port located in the in the base section.

19. A resonant sensor comprising:
a piezoresistive layer including a first section and a second section, at least one cantilever beam connecting the first section and the second section; and
a mechanical layer adjacent the piezoresistive layer, the mechanical layer including a base section and a mass section, at least one cantilever beam connecting the base section and the mass section,
the at least one cantilever beam of the piezoresistive layer and the at least one cantilever beam of the mechanical layer being spaced apart to define an gap, the gap having a height that is approximately equal to the distance between the at least one cantilever beam of the piezoresistive layer and a neutral plane of the at least one beam of the mechanical layer.

20. A method for forming a resonant sensor comprising:
providing a mechanical substrate layer;
depositing a thin metal layer;
patterning the thin metal layer to form metal traces and contact pads;
etching device layer to form the sensing beams;
etching the mechanical substrate layer to form top surface of a mechanical beam at a predetermined depth;
etching an opening in the mechanical substrate layer from a backside of the substrate layer to shape the mechanical beam, form the sensing beam, and form a base section and a mass section.
